(19) United States
(12) Patent Application Publication
(10) Pub. No.: US 2014/0014084 A1
(43) Pub. Date: Jan. 16, 2014

(54) WATERPROOF CAPACITIVE TOUCH SYSTEM FOR AN APPLIANCE

(71) Applicant: John Robert Rudolph, Antioch, TN (US)

(72) Inventor: John Robert Rudolph, Antioch, TN (US)

(73) Assignee: ELECTROLUX HOME PRODUCTS, INC., Charlotte, NC (US)

(21) Appl. No.: 13/546,287

(22) Filed: Jul. 11, 2012

(51) Int. Cl. G01R 27/04; F24C 15/00

(52) U.S. Cl. 126/1 R; 324/629

(57) ABSTRACT

Provided is a touch-sensitive input apparatus including a capacitive sensor with a plurality of adjacent capacitive, touch-sensing regions for detecting a foreign object in close proximity to a surface of the capacitive sensor. The foreign object can be brought into contact with, or at least in close proximity to the surface to enter an instruction for controlling a device associated with the touch-sensitive input apparatus. A controller receives a signal indicative of a capacitance sensed by a first region included in the plurality of touch-sensing regions during application of a shield signal to a second region included in the plurality of touch-sensing regions. The second region is located adjacent to the first region.

### BACKGROUND OF THE INVENTION

1. Field of the Invention

This application relates generally to an appliance controller and, more specifically, to a water-resistant, touch-sensitive controller for receiving input commands for controlling an aspect of an appliance.

2. Description of Related Art

Current capacitive touch electronics found in appliances can become insensitive or non-responsive to being contacted by a finger on which moisture has collected. Additionally, during the cooking process it is common for liquids such as water to boil over or otherwise splash out of a cooking vessel. When such liquids land on a conventional capacitive sensor they can alter the sensed capacitance, possibly inputting a signal that affects an operational feature of the appliance without knowledge/interaction by the user.

Attempts to alleviate the impact of moisture on an array of capacitive touch sensors have traditionally involved depositing a dedicated copper shield surrounding the array. The shield is dedicated to counteracting parasitic capacitance, and conducts a signal to negate the parasitic capacitance caused by the presence of conductive liquid droplets on the touch surface. Offsetting this parasitic capacitance with the dedicated shield located externally of the array of touch sensors allows the system to detect an actual touch in the presences of the liquid on the touch surface. As electronic circuits become smaller and more technology is added to appliances, there is often insufficient space available to deposit the dedicated shield outside of the array of touch sensors.

### BRIEF SUMMARY OF THE INVENTION

Accordingly, there is a need in the art for a touch-sensitive system that mitigates an effect of a conductive liquid present on a surface of the touch-sensitive system. The system includes a capacitive sensor that includes a plurality of adjacent capacitive, touch-sensing regions, each for detecting a user-input instruction to control operation of a component of an appliance. The touch-sensitive system can mitigate the effect of the conductive liquid without a conductive shield adjacent to the plurality of touch-sensing regions dedicated, or dedicated at least primarily for conducting a signal to counteract parasitic capacitance.

According to one aspect, the subject application involves a touch-sensitive input apparatus that includes a capacitive sensor including a plurality of adjacent capacitive, touch-sensing regions for detecting a foreign object in close proximity to a surface of the capacitive sensor. The foreign object can be brought into contact with, or at least in close proximity to the surface to enter an instruction for controlling a device associated with the touch-sensitive input apparatus. A controller is operatively connected to the plurality of touch-sensing regions to receive a signal indicative of a capacitance sensed by a first region included in the plurality of touch-sensing regions during application of a shield signal to a second region included in the plurality of touch-sensing regions. The second region is immediately adjacent to the first region.

According to another aspect, the subject application involves a method of sensing an input utilizing a capacitive sensor. According to such an aspect, the capacitive sensor includes a plurality of adjacent capacitive, touch-sensing regions for detecting a foreign object in close proximity to a surface of the capacitive sensor and receiving a user-input instruction for controlling a device associated with the touch-sensitive input apparatus. The method of the present aspect includes designating a first region included in the plurality of touch-sensing regions as an active sensor that is to sense a capacitance value for determining whether the foreign object is located adjacent to the first region. A second region included in the plurality of touch-sensing regions is designated as a shield sensor to which a shield signal is to be applied. The second region can be immediately adjacent to the first region. A signal indicative of the capacitance value sensed by the first region while the shield signal is applied to the second region is received. The second region can then be designated as the active sensor that is to sense another capacitance value for determining whether the foreign object is located adjacent to the second region. A second signal indicative of the capacitance value sensed by the second region while the shield signal is applied to at least one of the plurality of touch-sensing regions is also received.

According to another aspect, the subject application involves a cooking appliance that includes a heating device that is operable to elevate a temperature of a food item. A support is provided to maintain a position of the food item adjacent to the heating device. A capacitive sensor is also provided, and includes a plurality of adjacent capacitive, touch-sensing regions for detecting a foreign object in close proximity to a surface of the capacitive sensor entering an instruction to control operation of the heating device. A controller is operatively connected to the plurality of touch-sensing regions to receive a signal indicative of a capacitance sensed by a first region included in the plurality of touch-sensing regions during application of a shield signal to a second region included in the plurality of touch-sensing regions. The second region is immediately adjacent to the first region.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF SEVERAL VIEWS OF THE DRAWING

The invention may take physical form in certain parts and arrangement of parts, embodiments of which will be described in detail in this specification and illustrated in the accompanying drawings which form a part hereof and wherein:

FIG. 1 shows an illustrative embodiment of a cooking appliance including a touch-sensitive input apparatus;

FIG. 2 shows an illustrative embodiment of a printed circuit board supporting a plurality of capacitive sensors and a controller for a touch-sensitive input apparatus;

FIG. 3A shows an illustrative embodiment of a capacitive sensor including a plurality of touch-sensing regions arranged in an arcuate pattern;

FIG. 3B shows another illustrative embodiment of a capacitive sensor including a plurality of touch-sensing regions arranged in a linear pattern; and

FIG. 4 is a flow diagram graphically depicting an illustrative embodiment of a method of sensing an input utilizing a capacitive sensor.

### DETAILED DESCRIPTION OF THE INVENTION

Certain terminology is used herein for convenience only and is not to be taken as a limitation on the present invention. Relative language used herein is best understood with reference to the drawings, in which like numerals are used to identify like or similar items. Further, in the drawings, certain features may be shown in somewhat schematic form.

It is also to be noted that the phrase “at least one of”, if used herein, followed by a plurality of members herein means one of the members, or a combination of more than one of the members. For example, the phrase “at least one of a first widget and a second widget” means in the present application: the first widget, the second widget, or the first widget and the second widget. Likewise, “at least one of a first widget, a second widget and a third widget” means in the present application: the first widget, the second widget, the third widget, the first widget and the second widget, the first widget and the third widget, the second widget and the third widget, or the first widget and the second widget and the third widget.

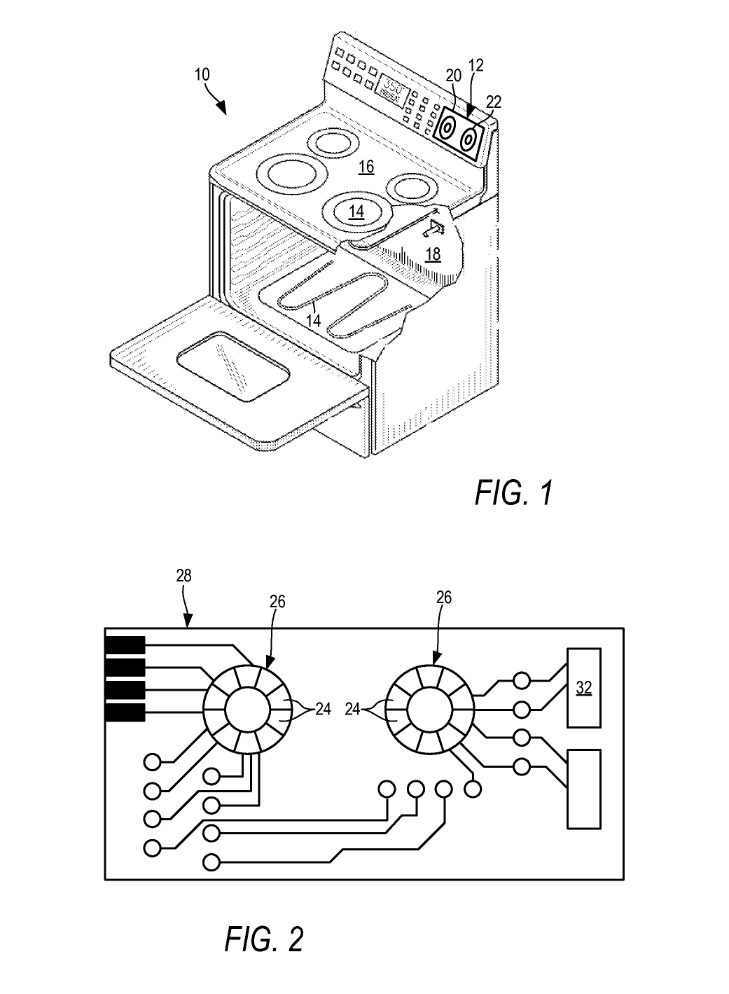

FIG. 1 shows an illustrative embodiment of a cooking appliance 10 that includes a touch-sensitive input apparatus 12 through which a user can input instructions for controlling operation of one or more heating elements 14 or other operational component of the cooking appliance 10. The heating element 14 can include a burner element provided to a stovetop 16, an oven element such as a bake and/or broil element disposed within an oven chamber 18, any other device operable to elevate the temperature of a food item (not shown), or any combination thereof. A surface of the cooktop 16, a rack or shelf in the oven chamber 18, or other suitable support on which the food item can be placed and supported adjacent to a heating device 14 can also be provided.

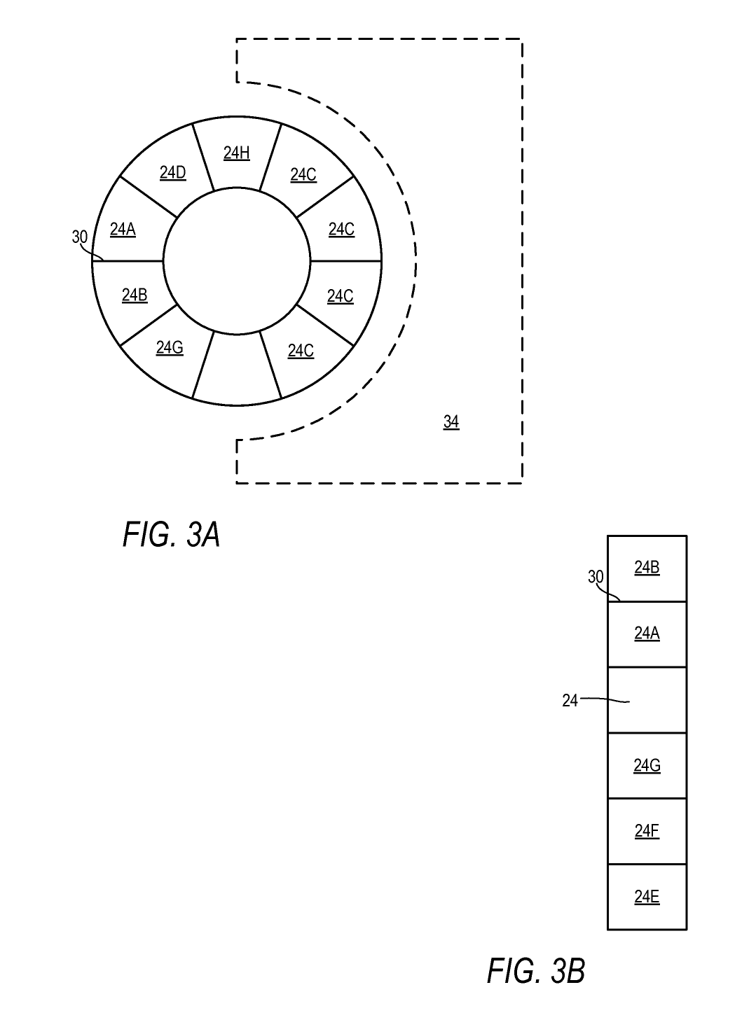

The touch-sensitive input apparatus 12 can include a decorative overlay 20 visible to a user facing the cooking appliance 10 from the front. The decorative overlay 20 presents a graphical user interface to the user of the cooking device 10. The embodiment of the decorative overlay 20 in FIG. 1 includes a pair of dial-shaped outlines 22. The outlines 22 identify a region of the exposed surface of the decorative overlay 20 along which a user can move a finger or other foreign object to input an instruction via the touch-sensitive input apparatus 12. The region can, for example, extend over a plurality of touch-sensing regions (referred to generally at 24, and individually at 24A-24H in FIGS. 2, 3A and 3B) of a capacitive sensor 26, arranged in a pattern to collectively form a variable sensor, also referred to as a slider sensor, described below. The variable embodiment of the capacitive sensor 26 allows a user to move a finger or other foreign object having a dielectric value different than that of air in the ambient environment along the surface of the decorative overlay 20, which overlays the pattern of touch-sensing regions 24. Although different foreign objects may suffice, the input of instructions via the touch-sensitive input apparatus 12 will be discussed utilizing the user's finger for the sake of clarity. As the user's finger is moved along the surface of the decorative overlay 20 within the outlines 22 in a first direction, that finger passes over the plurality of touch-sensing regions 24 of the capacitive sensor 26. The direction of movement is sensed based on signals transmitted by the touch-sensing regions 24, and an instruction to increase the power supplied to the heating element 14, and thereby raise the cooking temperature of the cooking appliance 10 is input. Likewise, As the user's finger is moved along the surface of the decorative overlay 20 within the outlines 22 in a second direction, that finger passes over the plurality of touch-sensing regions 24 of the capacitive sensor 26. Again, the direction of movement is sensed based on signals transmitted by the touch-sensing regions 24, and an instruction to decrease the power supplied to the heating element 14, and thereby lower the cooking temperature of the cooking appliance 10 is input.

FIG. 2 shows an embodiment of a printed circuit board (“PCB”) 28 supporting components that cooperate to render the touch-sensitive input apparatus 12 operable. The touch-sensitive input apparatus 12 receives an instruction by sensing the effect of a user's finger on the capacitance sensed by the plurality of touch-sensing regions 24 forming the capacitive sensor 26 as the finger passes over those touch-sensing regions 24. The touch-sensing regions 24 can be any type of capacitive sensor, such as a mutual capacitance sensor, a surface capacitance sensor, a projected capacitance sensor, a self-capacitance sensor, etc. . . . Further, the regions 24 can be constructed from any suitable sensing material such as a reinforced epoxy material commonly referred to as FR-4, copper, Indium tin oxide, printed ink, etc. . . . and other materials as is known in the art. For the illustrative embodiment shown in FIG. 2, and in FIG. 3A, the touch-sensing regions 24 are arranged in an arcuate pattern on the PCB 28, which can optionally form a complete circle, as shown. However, the touch-sensing regions 24 can be arranged adjacent to each other in any desired, substantially continuous pattern over which a user can move a finger to alter the capacitance value sensed by the touch-sensing regions 24 and thereby input a corresponding instruction.

As mentioned, the pattern formed by the touch-sensing regions 24 can be substantially continuous. The finger can be moved from a first touch-sensing region 24 to a second, contiguous touch-sensing region 24 as part of a continuous motion, optionally without encountering any extended gaps of dielectric material between the first and second touch-sensing regions 24. For instance, with reference to the embodiment of the capacitive sensor 26 shown in FIG. 3A, the user can move a finger in a counterclockwise direction from one touch-sensing region 24A to a contiguous touch-sensing region 24B that is immediately adjacent (i.e., nearest to, and not separated by another touch-sensing region) to the touch-sensing region 24A. In moving between the two touch-sensing regions 24A, 24B the user's finger crosses a boundary region 30 (represented by a line) formed from a dielectric material insulating the two regions 24A, 24B from each other. A dimension of the boundary region 30 extending between the touch-sensing regions 24A, 24B is insufficient for the user's finger to be completely removed from both touch-sensing regions 24A, 24B while traveling there between.

An alternate embodiment of a pattern of the touch-sensing regions 24 of the capacitive sensor 26 is shown in FIG. 3B. As shown, the touch-sensing regions 24 are arranged in a linear pattern. In a manner analogous to the description above pertaining to the arcuate arrangement, the user's finger can be moved in linear directions up and down the vertical pattern shown in FIG. 3B to input an instruction for a relative adjustment of the power supplied to a heating element 14 or to otherwise adjust operation of a portion of the cooking appliance 10. For instance, the user can slide a finger in a vertically-upward direction from one touch-sensing region 24A to a contiguous touch-sensing region 24B that is immediately adjacent to the touch-sensing region 24A. In moving between the two touch-sensing regions 24A, 24B the user's finger crosses a boundary region 30 (again represented by a line) formed from a dielectric material insulating the two regions 24A, 24B from each other. Based, at least in part, on the capacitance sensed by the touch-sensing regions 24A, 24B as the finger is slid from one to the other, it can be determined that the user has entered an instruction to increase an operational parameter of the cooking appliance 10.

Although an arcuate pattern and a linear pattern have been shown and described, other desired layouts of the touch-sensing regions 24 are also considered within the scope of the present disclosure.

Referring once again to FIG. 2, a controller 32 is also provided to the touch-sensitive input apparatus 12 and is operatively connected to the plurality of touch-sensing regions 24. The controller 32 can include electronic and/or electric circuit hardware components, and optionally a computer processing component and a non-transitory computer-readable memory component storing computer-executable instructions to be executed by the computer processing component. For example, the controller 32 can include a microprocessor, optionally with an embedded memory, such as a general-purpose or specifically-adapted digital signal processor (“DSP”), an application specific integrated circuit (“ASIC”), a field programmable gate array (“FPGA”), or any combination thereof

Regardless of its configuration, the controller 32 is operable to receive signals from the capacitive sensor 26 and determine whether an instruction has been input based on the received signals. The controller 32 is also operable to designate one or more of the touch-sensing regions 24 that can sense a capacitance corresponding to an instruction input with the user's finger as a shield sensor. A shield signal is caused to be applied to the touch-sensing region 24 designated as the shield sensor as described below to shield an immediately-adjacent touch-sensing region 24 that is actively sensing a capacitance corresponding to an instruction input to control operation of a portion of the cooking appliance 10.

Using one or more of the touch-sensing regions 24, when not actively being used to sense a capacitance indicative of an instruction, as a shield sensor eliminates the need for a separate shield 34 dedicated primarily for shielding purposes, such as that shown in broken lines in FIG. 3A. The dedicated shield 34 is shown in FIG. 3A to illustrate that such a dedicated shield 34 would be necessarily located adjacent to, but electrically insulated from (i.e., separate from) the touch-sensing regions 24 of the capacitive sensor 26. But it is understood that the dedicated shield 34 is absent from the touch-sensitive input apparatus 12 described herein, and not include as part of the PCB 28 appearing in FIG. 2. To mitigate the effect of a substance such as water, food or other material on the user's finger, for example, at the surface of the decorative overlay 20 on the sensed capacitance, a shield signal would be applied to the dedicated shield 34 while one of the touch-sensing regions 24C near the shield 34 in FIG. 3A sensed a capacitance value to determine whether an instruction was being input. As can be seen in FIG. 3A, however, the dedicated shield 34 required to counteract the effect of a substance such as water on the capacitance sensed by several adjacent touch-sensing regions 24 is very large, and requires a substantial amount of space to implement. A dedicated shield required in addition to the capacitive sensor 26 and consuming this substantial amount of space interferes with the addition of new features to devices such as the cooking appliance 10.

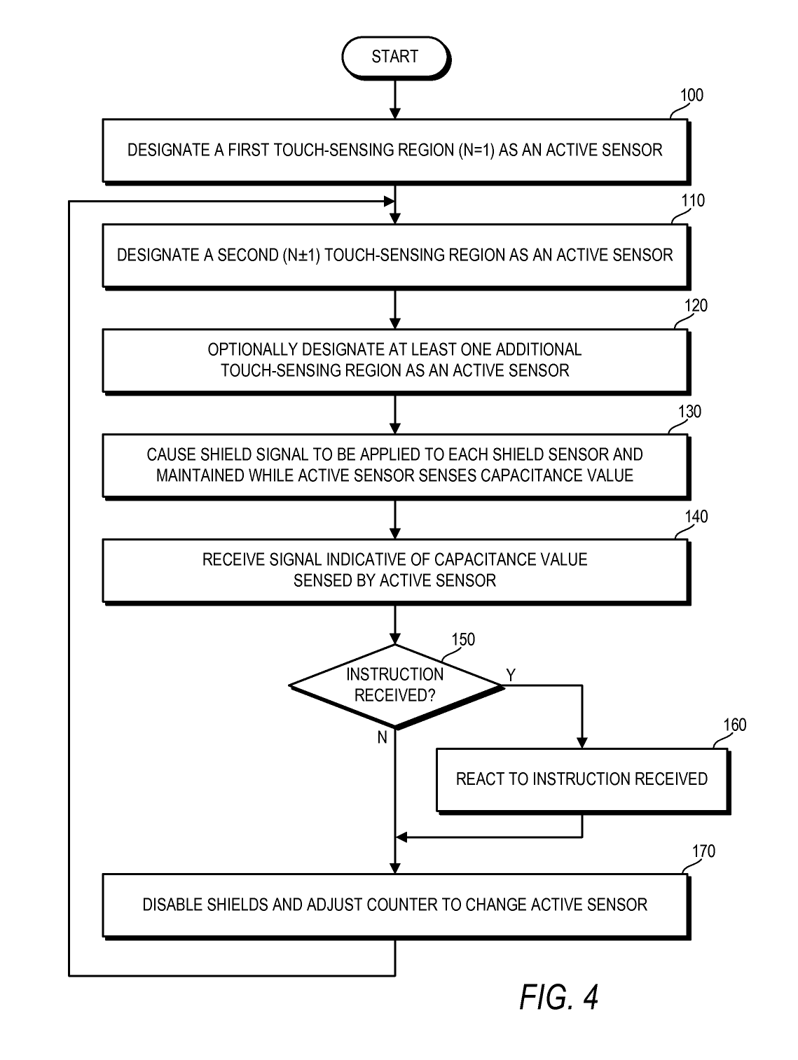

An illustrative embodiment of a method of sensing an input utilizing the capacitive sensor 26 can be understood with reference to the flow diagram appearing in FIG. 4. Upon being powered on, the touch-sensitive input apparatus 12 can conduct an initialization routine and clear all designations of any of the touch-sensing regions 24 as an active sensor and a shield region. An active sensor is any of the touch-sensing regions 24 that is to be used to actively sense a capacitance and convert the sensed capacitance into a signal that is transmitted to be received by the controller 32. Once the touch-sensitive input apparatus 12 has been initialized the controller 32 can establish a counter to an initial value (e.g., N=1) and thereby designate a first touch-sensing region 24A (FIG. 3A) as the active region at step 100.

To shield against the effect of any substance such as water, for example, present at a surface of the decorative overlay 20 or otherwise close enough to the touch-sensitive input apparatus 12 to affect the capacitance value sensed by the active region, the controller 32 designates an adjacent touch-sensing region 24B as a shield sensor at step 110. A shield signal is applied to each shield sensor while the active sensor senses the capacitance value that is to be transmitted to the controller 32 for detecting the input of an instruction as described herein. It is not necessary for the shield signal to be applied simultaneously with the sensing operation performed by the active sensor. Instead, the shield signal can be previously applied to the shield sensor and maintained while the capacitance value is sensed by the active sensor. For the embodiment shown in FIG. 3A, the shield sensor is the touch-sensing region 24B that is immediately adjacent to the active sensor (i.e., not separated from the active sensor by another touch-sensing region 24). Thus, the controller can identify and designate an appropriate touch-sensing region 24B as the shield sensor by incrementing or decrementing the counter value assigned to the touch-sensing region 24A designated as the active sensor by one unit (N±1).

According to an alternate embodiment, the controller 32 can also optionally designate, at step 120, an additional, third touch-sensing region 24D included among the plurality of touch-sensing regions 24 as another shield sensor to which a shield signal is to be applied to shield the active sensor while the active sensor senses the capacitance value. The third touch-sensing region 24D is a different one of the touch-sensing regions 24 than the touch-sensing region 24B designated as a shield sensor. And according to the embodiment shown in FIG. 3A, the third touch-sensing region 24D is also immediately adjacent to, and separated from the touch-sensing region 24B also designated as a shield sensor by the active sensor. In other words, the touch sensing regions 24B, 24D are each immediately adjacent to the touch sensing region 24A designated as the active sensor, and are on opposite sides of the active sensor to thoroughly shield the active sensor.

The designation of a second shield sensor can optionally be dependent upon the availability of another one of the touch-sensing regions 24 on an opposite side of the active sensor relative to the first shield sensor designated. For instance, the embodiment of the capacitive sensor 26 shown in FIG. 3B includes a linear arrangement of the touch-sensing regions. If the touch-sensing region 24E is designated to be the active sensor, the touch-sensing region can be designated by the controller 32 to be a shield sensor to which the controller 32 can cause the shield signal to be applied for the sensing of the capacitance value by the active sensor. But since there are no other touch-sensing regions 24 separated from the touch-sensing region 24F by the active sensor in FIG. 3B, the controller 32 can optionally not designate an additional one of the touch-sensing regions 24 as a second shield sensor.

According to an alternate embodiment, the controller 32 can optionally designate the touch-sensing region 24G in FIG. 3B, which is arranged on the same side of the active sensor as the touch-sensing region designated as a shield sensor, to be a second shield sensor. For the embodiment in FIG. 3A, the touch-sensing regions 24 are arranged in a continuous, circular pattern and do not have a terminal touch sensing region arranged as the touch-sensing region 24E of the embodiment shown in FIG. 3B. However, one or both of the touch-sensing regions 24G, 24H can be designated by the controller 32 to be an additional shield sensor on either or both sides of the touch-sensing region 24A designated as the active sensor. Thus, a plurality of touch-sensing regions 24 arranged in either or both directions along the capacitive sensor 26 from the active sensor can be designated as shield sensors to suitably shield the active sensor, without requiring a dedicated shield 34 such as that described above.

As mentioned above, a shield signal is being applied to each shield sensor at step 130, optionally under the control of the controller 32, while the active sensor is being used to sense the capacitance value. The controller 32, at step 140, can scan the active sensor and retrieve the signal indicative of the capacitance value sensed by the active sensor while the controller 32 is acting in an active mode, or otherwise receive a transmitted signal indicative of the sensed capacitance value while the controller 32 is acting in a passive mode. At step 150, based at least in part on this signal received, the controller 32 determines whether the capacitance value corresponds to the presence of the user's finger on or near the surface of the decorative overlay 20 at a location corresponding to touch-sensing region 24 that transmitted the signal. If so, the controller 32 can, at step 160, transmit a control signal for bringing about the desired change to an operational feature of the cooking appliance 10 (e.g., adjusting the power supplied to a heating element 14), or log the capacitance value until an additional capacitance value is sensed by one or more of the adjacent touch-sensing regions 24 to determine a direction, and optionally a distance along the capacitive sensor 26 the user's finger is being moved to input the instruction before transmitting the control signal, for example. The method can resume following the reaction to a received instruction.

If the determination at step 150 is negative, the method resumes without transmission of the control signal to bring about any changes with respect to an operational feature of the cooking appliance 10. At step 170, all of the shield sensors are disabled, which involves terminating application of the shield signal to those shield sensors. The controller 32 can also adjust the counter by incrementing or decrementing the counter, for example, to designate the next one of the touch-sensing regions 24 as the active sensor. With continued reference to the illustrative embodiment shown in FIG. 4, the counter can be incremented by one unit (N=N+1) to designate the new active sensor for the second iteration. The new active sensor for the second iteration can optionally be a touch-sensing region 24 that was previously, optionally during the immediately preceding iteration, designated as a shield sensor. In other words, a shield sensor can be re-designated as the active sensor during a subsequent iteration. For instance, the touch-sensing region 24B in FIG. 3A designated as a shield sensor in the immediately preceding iteration can be designated as the active sensor for the subsequent iteration. The method then returns to step 110 where at least one shield sensor, and optionally a plurality of shield sensors are designated.

Although the method is described with reference to FIG. 4 as an iterative method where each of the touch-sensing regions 24 are iteratively surveyed to detect a capacitance value according to a clock signal or other signal, for example, it is to be understood that the method can be implemented by the controller 32 through the use of interrupts, for example, or any other technique. An interrupt routine can, for example, allow the controller 32 to react to the receipt of a signal indicative of a sensed capacitance value by one or more of the touch-sensing regions 24 without departing from the scope of the present disclosure.

Illustrative embodiments have been described, hereinabove. It will be apparent to those skilled in the art that the above devices and methods may incorporate changes and modifications without departing from the general scope of this invention. It is intended to include all such modifications and alterations within the scope of the present invention. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A touch-sensitive input apparatus comprising:
a capacitive sensor comprising a plurality of adjacent capacitive, touch-sensing regions for detecting a foreign object in close proximity to a surface of the capacitive sensor entering an instruction for controlling a device associated with the touch-sensitive input apparatus; and
a controller operatively connected to the plurality of touch-sensing regions to receive a signal indicative of a capacitance sensed by a first region included in the plurality of touch-sensing regions during application of a shield signal to a second region included in the plurality of touch-sensing regions, wherein the second region is immediately adjacent to the first region.

2. The touch-sensitive input apparatus of claim 1, wherein the plurality of touch-sensing regions of the capacitive sensor are arranged in a pattern to collectively form a variable capacitive sensor that senses a request for relative adjustment of an operational parameter of the device associated with the touch-sensitive input apparatus based on movement of the foreign object along the surface of the capacitive sensor.

3. The touch-sensitive input apparatus of claim 2, wherein the pattern comprises at least one of an arcuate region and a linear region along which the touch-sensing regions are arranged.

4. The touch-sensitive input apparatus of claim 1, wherein the signal received by the controller is indicative of the capacitance sensed by the first region while the shield signal is being applied to the second region and a third region included in the plurality of touch-sensing regions.

5. The touch-sensitive input apparatus of claim 4, wherein the third region is immediately adjacent to, and separated from the second region by the first region.

6. The touch-sensitive input apparatus of claim 4, wherein the third region is separated from the first region by the second region.

7. The touch-sensitive input apparatus of claim 1, wherein the signal received by the controller is indicative of the capacitance sensed by the first region while the shield signal is being applied to a plurality of regions on each opposite side of the first region.

8. The touch-sensitive input apparatus of claim 1, wherein the touch-sensing regions are not shielded by a separate conductive shield that is primarily dedicated for conducting the shield signal to minimize an effect of a substance present at the surface of the capacitive sensor on the capacitance sensed by the first region.

9. A method of sensing an input utilizing a capacitive sensor, the capacitive sensor comprising a plurality of adjacent capacitive, touch-sensing regions for detecting a foreign object in close proximity to a surface of the capacitive sensor and receiving a user-input instruction for controlling a device associated with the touch-sensitive input apparatus, the method comprising:
designating a first region included in the plurality of touch-sensing regions as an active sensor that is to sense a capacitance value for determining whether the foreign object is located adjacent to the first region;
designating a second region included in the plurality of touch-sensing regions as a shield sensor to which a shield signal is to be applied, wherein the second region is immediately adjacent to the first region;
receiving a signal indicative of the capacitance value sensed by the first region while the shield signal is applied to the second region;
designating the second region as the active sensor that is to sense a capacitance value for determining whether the foreign object is located adjacent to the second region; and
receiving a second signal indicative of the capacitance value sensed by the second region while the shield signal is applied to at least one of the plurality of touch-sensing regions.

10. The method of claim 9 further comprising designating a third region included in the plurality of touch-sensing regions as a shield sensor to which a shield signal is to be applied, wherein the third region is different than the second region and is immediately adjacent to the first region.

11. The method of claim 10, wherein the first region is disposed between the second region and the third region.

12. The method of claim 10, wherein the signal received is indicative of the capacitance value sensed by the first region while the shield signal is applied to both the second region and the third region.

13. The method of claim 9 further comprising designating a third region included in the plurality of touch-sensing regions as a shield sensor to which a shield signal is to be applied, wherein the third region is different than the second region and is immediately adjacent to the second region.

14. The method of claim 9, wherein the capacitance value is sensed by the first region without being shielded by a separate conductive shield, not included in the plurality of touch-sensing regions for accepting the user-input instruction, that is primarily dedicated for conducting the shield signal to minimize an effect of a substance present at the surface of the capacitive sensor.

15. A cooking appliance comprising:
a heating device that is operable to elevate a temperature of a food item;
a support on which the food item can be placed and supported adjacent to the heating device;
a capacitive sensor comprising a plurality of adjacent capacitive, touch-sensing regions for detecting a foreign object in close proximity to a surface of the capacitive sensor entering an instruction to control operation of the heating device; and
a controller operatively connected to the plurality of touch-sensing regions to receive a signal indicative of a capacitance sensed by a first region included in the plurality of touch-sensing regions during application of a shield signal to a second region included in the plurality of touch-sensing regions, wherein the second region is immediately adjacent to the first region.

16. The cooking appliance of claim 15, wherein the touch-sensing regions are not shielded by a separate conductive shield, not included among the plurality of touch-sensing regions for detecting the foreign object, for conducting the shield signal to minimize an effect of a substance present at the surface of the capacitive sensor on the capacitance sensed by the first region.

17. The cooking appliance of claim 15, wherein the plurality of touch-sensing regions of the capacitive sensor are arranged in a pattern to collectively form a variable capacitive sensor that senses a request for relatively adjusting a power level at which the heating device is operating based on movement of the foreign object along the surface of the capacitive sensor.
